(19) United States
(12) Patent Application Publication
(10) Pub. No.: US 2010/0165581 A1
(43) Pub. Date: Jul. 1, 2010

(54) PACKAGE FOR MICRO-ELECTRO-MECHANICAL SYSTEMS OF THE MEMS TYPE AND CORRESPONDING MANUFACTURING PROCESS

(75) Inventors: Federico Giovanni ZIGLIOLI, Gessate (MI) (IT); Mark Andrew SHAW, Milano (IT)

Correspondence Address: GRAYBEAL JACKSON LLP, 400 - 108TH AVENUE NE, SUITE 700, BELLEVUE, WA, 98004, US

(73) Assignee: STMICROELECTRONICS S.R.L., Agrate Brianza (IT)

(21) Appl. No.: 12/645,093

(22) Filed: Dec. 22, 2009

(30) Foreign Application Priority Data
Dec. 24, 2008 (IT) MI2008A002321

(51) Int. Cl. H05K 5/00; H01L 29/84; H01L 21/02; H05K 1/00; H05K 7/00

(52) U.S. Cl. 361/730; 257/415; 438/51; 361/752; 361/757; 361/749; 361/728; 257/414; 257/700; 438/21; 257/E29.324; 257/E21.002; 438/48; 438/124

(57) ABSTRACT

An embodiment of a package for Micro-Electro-Mechanical Systems of the MEMS type comprising a base for the assembly of said MEMS and a protective envelope, for containing the MEMS. The base is a multi-layer structure with at least one layer of composite material to make a substrate and at least one flexible wing projecting from the substrate, such base being a monolithic element suitable for being connected to external connection tracks.

### PRIORITY CLAIM

The present application claims the benefit of Italian Patent Application Serial No.: MI2008A002321, filed Dec. 24, 2008, which application is incorporated herein by reference in its entirety.

### TECHNICAL FIELD

An embodiment of the present invention refers to a package for Micro-Electro-Mechanical Systems of the MEMS type.

More specifically, an embodiment of the invention refers to a package for MEMS comprising a base for the assembly of said MEMS and a protective envelope for containing said MEMS.

An embodiment of the invention also refers to a process for manufacturing a package for MEMS.

### BACKGROUND

As known, MEMS is the acronym for Micro-Electro-Mechanical Systems and identifies a technology for integration on the same base, in particular a semiconductor substrate, of devices of various kinds, mechanical and electronic/electrical, integrated in highly miniaturized form. Generally, the semiconductor substrate is a thin die made from silicon or another semiconductor material.

In particular, the MEMS technology combines the opto-mechanical properties of mechanical devices with the electrical properties of integrated electronic circuits allowing for:

monitoring of the surrounding environment, collecting suitable information through sensors for measuring mechanical, biological thermal, optical or magnetic events through the mechanical devices;

processing of such information collected through the electronic devices with integrated circuit, as well as

response with possible actions enabling suitable actuators or simply detecting possible variations that have occurred in the area in a certain time period.

In this way, MEMS technology is widely used in various fields, for example industrial for making household appliances/intelligent home management systems, automobile, aerospace, medical for making probes, surgical instruments, catheters and others. For example, it is possible to make optical detectors, pressure sensors for alarms, accelerometers, gyroscopes, electric motors, ph measurers, voice recognition devices and other numerous devices.

As can easily be imagined, bulky and expensive devices currently used in the field can advantageously be made with MEMS technology in an extremely miniaturized way.

In particular, this miniaturization is linked to the fact that the mechanical and electromechanical devices integrated in the same semiconductor substrate are obtained by means of suitable and selective attachments of the layers used to make the electronic devices, with possible addition of specific further structural layers.

With such miniaturization, there is a need to ensure adequate protection of the mechanical and electronic/electrical devices that make up a MEMS. Indeed, they are delicate and their operation could be extremely compromised both by possible accidental shock and by the conditions of the surrounding environment in which they have to operate, like for example acidity/basicity but also noise or other conditions. Such protection is made by incorporating MEMS components in a suitable package.

However, the multiple applications may have different requirements and require the use of packages with characteristics that are in some cases in contrast with one another.

Indeed, for some applications the package should be rigid to protect the incorporated MEMS components. In other applications, the package should be flexible to allow an interaction between the MEMS components and the surrounding environment.

In order to obtain packages for MEMS of the rigid type the techniques used to obtain packages for electronic devices are currently used, in which the protective envelope is made by molding of an epoxy resin. It is thus possible to use a technique known by the acronym BGA (Ball Grid array) based upon which the packages have the protective envelope obtained by molding whereas the electrical connection terminals are obtained through a grid of hemispheres outside of the envelope. Alternatively, a technique known by the acronym SOIC or simply SO (Small-Outline Integrated Circuit) is used in which the electrical connection terminals consist of feet that project from a rigid box-shaped envelope, as for example illustrated in FIG. 1.

The technique known by the acronym QFN (Quad Flat No leads) or else the technique known by the acronym LGA (Land Grid Array) is also used. The packages obtained with such techniques are respectively illustrated in FIGS. 2 and 3, and in FIG. 4. In this case, the connection terminals are PADs or contact areas formed on a surface of the protective envelope.

The rigid MEMS packages thus obtained whilst advantageous from various points of view nevertheless have some drawbacks, in particular such packages are constrained by the feet or connection PADs with regard to assembly on a Printed Circuit Board PCB as can be seen from the examples illustrated in FIG. 6.

It is also known that design requirements also sometimes need the MEMS packages to be arranged on a PCB board or on a ceramic layer (for example for applications in the field of automobiles) with a particular orientation, inclined with respect to the PCB or to the ceramic layer with angulations such as to be able to interact with the surrounding environment and carry out their functionalities to the best of their capability.

In fact, the MEMS package made with the known techniques indicated and briefly explained above constrains and limits the use of the package itself.

Alternatively, it is known to make flexible MEMS packages, as described in US 2007/0013036A1 filed on 15 Jul. 2005, assigned to Silicon Matrix Pte Ltd, and which is incorporated by reference. Such an application teaches to position MEMS on a flexible semiconductor substrate in flat position and to form the package by bending one portion of the substrate on another, substantially forming a “sandwich”, with the interposition of a rigid spacing element between the two portions and with the MEMS components incorporated, as illustrated in FIG. 5.

The flexible MEMS packages thus obtained, whilst satisfactory from various points of view, have some drawbacks. They may be quite complex to make, and in particular the flexible semiconductor substrate may be difficult to handle and may require appropriate machinery that has objective difficulties in being integrated with the usual production lines, also involving an excessive increase in the manufacturing time and costs.

Basically, the MEMS packages made according to the prior art may have a configuration that limits their arrangement or complicates their manufacture and therefore may not be satisfactory from the point of view of versatility in arrangement, of practicality of connection and therefore of use, as well as of production costs.

### SUMMARY

A need has arisen for a MEMS package having structural and functional characteristics which overcome the limitations and/or drawbacks that still affect MEMS packages made according to the prior art.

An embodiment of the present invention is a package for MEMS on a base incorporating at least one flexible portion.

On the basis of such embodiment the technical problem is solved by a MEMS package as previously described wherein said base is a multi-layer structure with at least one layer of composite material that makes a substrate and at least one flexible wing projecting from said substrate, said base being a monolithic element suitable for being connected to external connection tracks.

Suitably, according to an embodiment of the present invention, the base is a printed circuit board PCB. Thanks to said base, monolithic element between substrate, and flexible wing, the package for MEMS according to an embodiment of the invention is associated with a PCB board or with a ceramic layer with maximum freedom without being constrained to any arrangement.

The protective envelope may be made from rigid plastic material, and it is associated with said substrate to define the package of the full-molded type. In this way, the MEMS components are associated with the multi-layer substrate and protected optimally, whereas the physical and electrical connection of the package to the board may take place with desired angulations according to the design requirements by means of the flexible wing.

The base, or monolithic element of the MEMS package, may have a further multi-layer substrate made similarly to the substrate and associated with it by means of the flexible wing and/or by means of a further additional wing.

This allows the board or circuit to be associated with one or more of the components constituting the base: the substrate, the further substrate, the wing or the further wing, thus making an MEMS package with maximum freedom of arrangement capable of satisfying any desired layout.

Such a configuration also makes it possible to obtain a package with two protective envelopes connected by a flexible wing and to place one protective envelope on top of the other.

An embodiment of a process for manufacturing a package for MEMS of the type described above comprises the following steps of:

providing a multi-layer base formed from a substrate with at least one layer of composite material and at least one flexible wing projecting from said substrate, said base being a monolithic element;

associating said MEMS components with the base;

making the protective envelope for the base;

connecting said base to external connection tracks.

### BRIEF DESCRIPTION OF THE DRAWINGS

Characteristics and advantages of a package and of a process according to one or more embodiments of the invention shall become clear from the following description of an example embodiment thereof, given for indicating and not limiting purposes with reference to the attached drawings.

FIGS. 1 to 5 illustrate different packages for MEMS made according to known techniques;

FIG. 6 illustrates two examples of applications of MEMS packages on PCBs;

FIG. 7 is a perspective view of a package according to a first embodiment of the present invention;

FIG. 8 is a longitudinal section view of the base of the package of FIG. 7;

FIG. 9 is a plan view of some MEMS components associated on a base made according to an embodiment of the present invention;

FIGS. 10 and 11 are respective perspective views of a second and a third embodiment of a MEMS package;

FIGS. 12, 13 and 14 are perspective views of a fourth embodiment of a MEMS package, in three different arrangements;

FIG. 15 is a plan view of some MEMS components associated with a second embodiment of a base;

FIG. 16 is a perspective view of a variant of the package of FIG. 12;

FIGS. 17 and 18 are perspective views respectively from above and from below of a fifth embodiment of a MEMS package;

FIGS. 19, 20, 21 and 22 are section views of a second, third, fourth and fifth embodiment of the base of the package;

FIG. 23 is a plan view of an embodiment of a strip comprising a plurality of bases for packages;

FIG. 24 is a perspective view from below of a portion of the strip of FIG. 23;

FIG. 25 is a plan view of a second embodiment of a strip comprising a plurality of bases for packages;

FIG. 26 is a cross section of FIG. 25 carried out according to the line I-I;

FIGS. 27 and 28 are respectively a plan view and a section view according to the line II-II of a third embodiment of a strip comprising a plurality of bases;

FIGS. 29, 30 and 31 show successive steps for making a plurality of MEMS packages from the strip of FIG. 27;

FIGS. 32, 33 and 34 illustrate three examples of devices comprising MEMS packages.

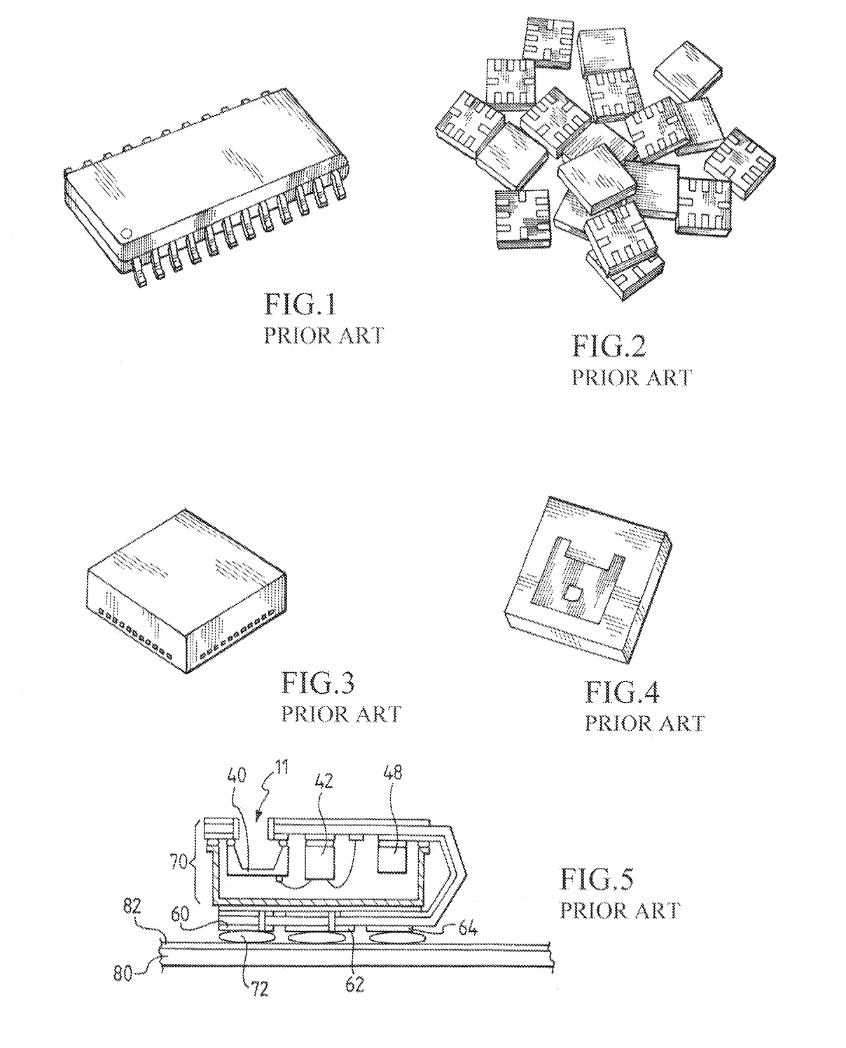

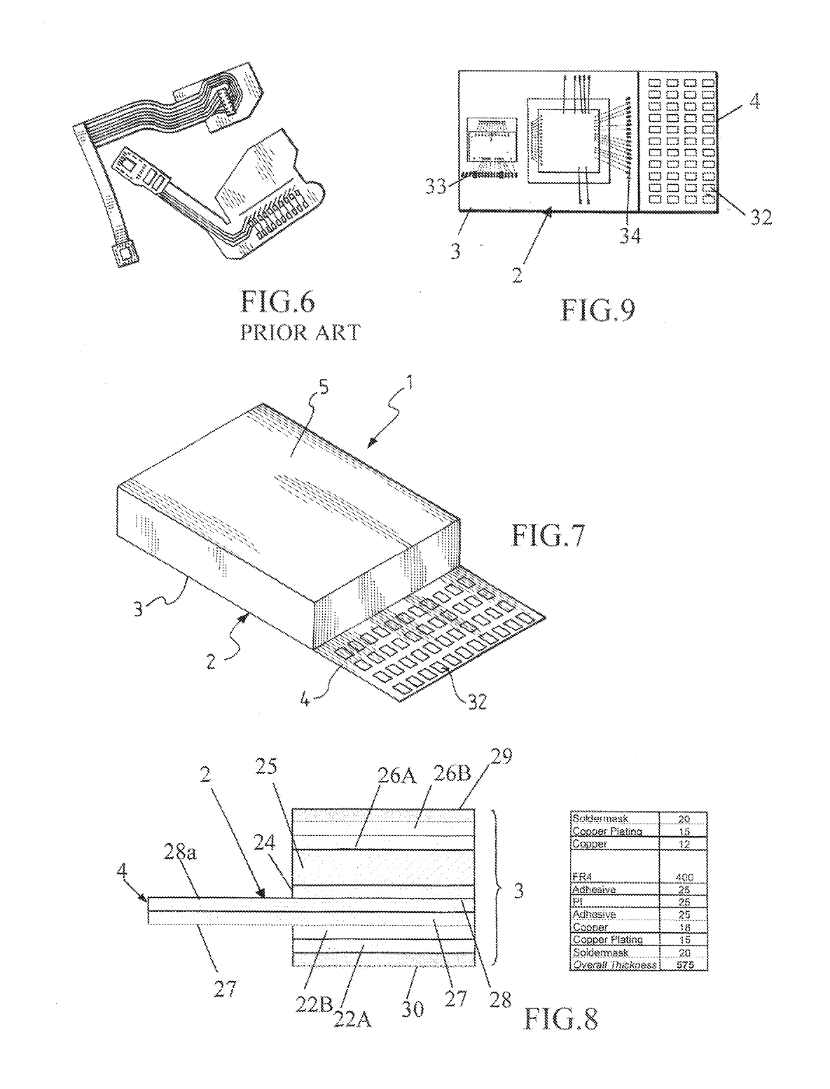

### DETAILED DESCRIPTION

With reference to such figures, a package for MEMS according to an embodiment of the present invention is globally indicated with 1.

The package 1, as illustrated in particular in FIG. 7, has a substantially box-shaped configuration and comprises a base 2, for the assembly of MEMS components, and a protective envelope 5 for containing and protecting such MEMS components.

The package/obtained with the MEMS components totally incorporated inside it is of the so-called full-molded type.

As illustrated in FIG. 8, the base 2 comprises a multi-layer substrate 3 comprising layers of composite material for making printed circuit boards PCB.

Furthermore, according to an embodiment of the present invention, the base 2 of the package/comprises at least one flexible wing 4 projecting from the side of the substrate 3 to define a single body with it.

The substrate 3 is a structure of stacked layers and comprises, for example in sequence starting from the bottom, a lower coating layer 30 (solder mask), a pair of lower conductive layers, 22A and 22B, generally made from copper or conductive material coated in copper, an adhesive layer 27 and a layer of plastic material 28, in particular polyamide, which is covered by a further adhesive layer 24 and by an inner layer 25 of composite material (like for example FR4, BT, or fibreglass or layers of aluminium). On top of the inner layer 25 there is a pair of upper conductive layers, 26A and 26B, and finally an upper coating layer 29.

Generally, the upper and lower coating layers 29, 30 are made from an insulating paint known as “solder resist” or “solder mask” that allows the portions of substrate 3 not intended for the welding of the MEMS components that will then be mounted to be protected from oxidation and from undesired electrical contacts.

The flexible wing 4, according to such an embodiment, comprises a portion 28a of the layer of plastic material 28 that lies on a portion 27a of the adhesive layer 27, such portions being an extension of the corresponding layers, adhesive 27 and of plastic material 28, respectively, which define the substrate 3.

The flexible wing 4 thus has a substantially lower thickness than the thickness of the substrate 3 and in particular has specific characteristics of rigidity.

Of course, the composition of the layers of the substrate 3 as well as of the flexible wing 4 is variable according to the design requirements.

The inner layer 25 is the heart of the substrate 3 and in particular defines its rigidity. The inner layer 25 may be a layer of type 4 Flame Retardant (FR4), Bismaleimide-Triazine (BT), liquid crystal polymer (LCP) or CEM-1 laminate, or else a layer of aluminium with a thickness of approximately from 50 to 1000 μm. Suitably, the layers that define the substrate 3 are separately micromachined with PCB (Printed Circuit Board) technology through precision mechanical micromachining, like for example numerical control milling, and suitable three-dimensional metallizations to obtain metalized through holes and/or buried channels and/or channels for micro fluidics applications, and fluid routing through the substrate. Further adhesive layers as well as the interposition of insulating layers, for example of pre-preg, which is a fabric made of glass mixed with resin, may be present between one layer and the other of the substrate 3 and/or of the flexible wing 4.

Moreover, all of the layers indicated above, as well as possible additional layers, may be connected together in a single final pressure assembly step, to make the base 2 as a monolithic element.

Moreover, the base 2 has inner electrical connection tracks 33 suitably made on the outer surfaces of the substrate 3 and possibly connected together through buried vias and/or channels 34 according to a predetermined layout and design specifications, as schematically illustrated in FIG. 9. Such inner electrical connection tracks 33, in a known way, allow the MEMS components that are housed in the substrate 3 itself to be electrically connected with each other.

As illustrated in FIGS. 7 and 9, the flexible wing 4 comprises connection areas or PADS 32 that allow the base 2 to be electrically connected to outer connection tracks and in particular to printed circuit boards PCB.

In accordance with a further variant embodiment of the base 2, the flexible wing 4, made with predetermined layers could be a housing for further MEMS components as well as in which case equipped with suitable specially provided connection tracks.

The rigid protective envelope 5 that, in the present embodiment, covers the base 2 and the MEMS components housed in it and electrically connected, has a box-shaped configuration and may be made by molding of a plastic material or resin.

The base 2 and in particular the flexible wing 4, form a single body with the substrate 3, but outside the protective envelope 5, allows a connection of the package/to external connection tracks according to a desired spatial arrangement. Such outer connection tracks can be normal printed circuit boards.

Moreover, the flexible wing 4 makes it possible to make suitable electrical connections to the MEMS components housed on the substrate 3 even in the case in which they are mechanically insulated and electrically shielded from the outside through the protective envelope 5.

An embodiment of the invention has numerous variants all of which are covered by the same concept.

In the following description we will refer to the package described above and details and cooperating parts with the same structure and function shall be indicated with the same reference numerals and reference marks.

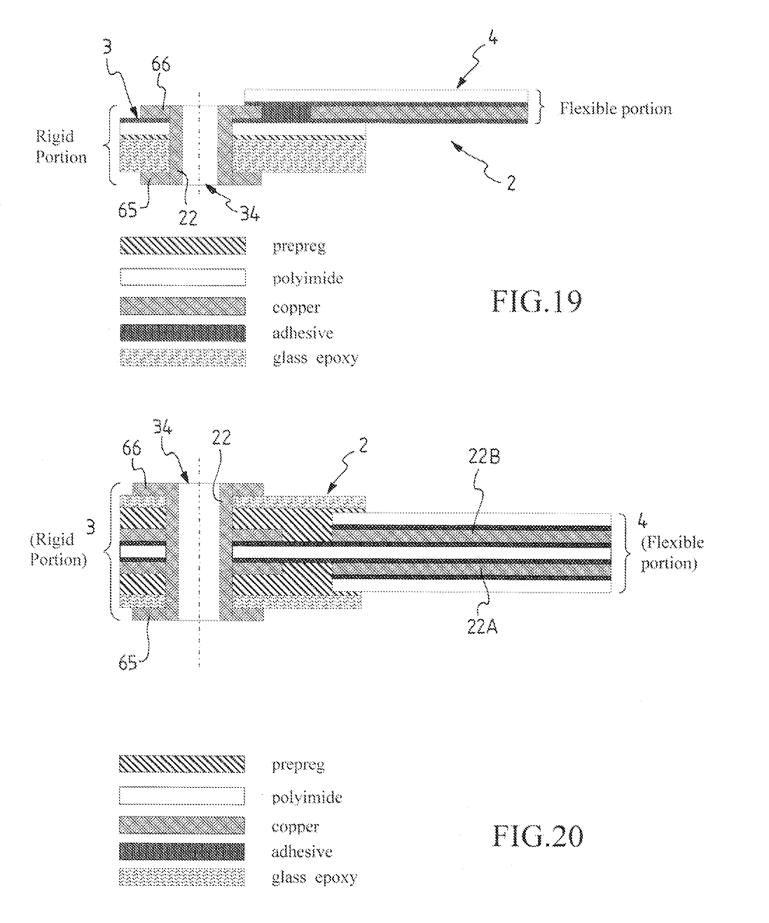

In accordance with variant embodiments of the base 2, the substrate 7 and the flexible wing 4 comprise a composition of variable and variously shaped layers. Some examples, for indicating purposes, are illustrated in FIGS. 19 to 22. In particular, the base 2, illustrated in FIG. 19, comprises a multi-layer substrate 3, which defines a rigid portion, and a flexible wing 4 projecting from the substrate 3 to define a single body with it.

According to such an embodiment, the flexible wing 4 projects from an upper surface of the substrate 3. Moreover, the flexible wing 4 has vias 34 or through holes, suitably metalized through a side coating with a copper layer 22. Such a copper layer 22 also defines suitable pads, 65 and 66, on the lower and upper surfaces of the substrate 3. In other embodiments, such a copper layer 22 can define further layers on the surfaces of the substrate 3.

In the embodiment illustrated in FIG. 20, the base 2 has a multi-layer substrate 3, which comprises a central core of overlying layers that extends to define a part of the flexible wing 4, projecting from the substrate 3. According to such an embodiment, the central core has a pair of layers of copper, 22A and 22B, suitable for making suitable electrical connection tracks in the multi-layer substrate 3 and also in the flexible wing 4.

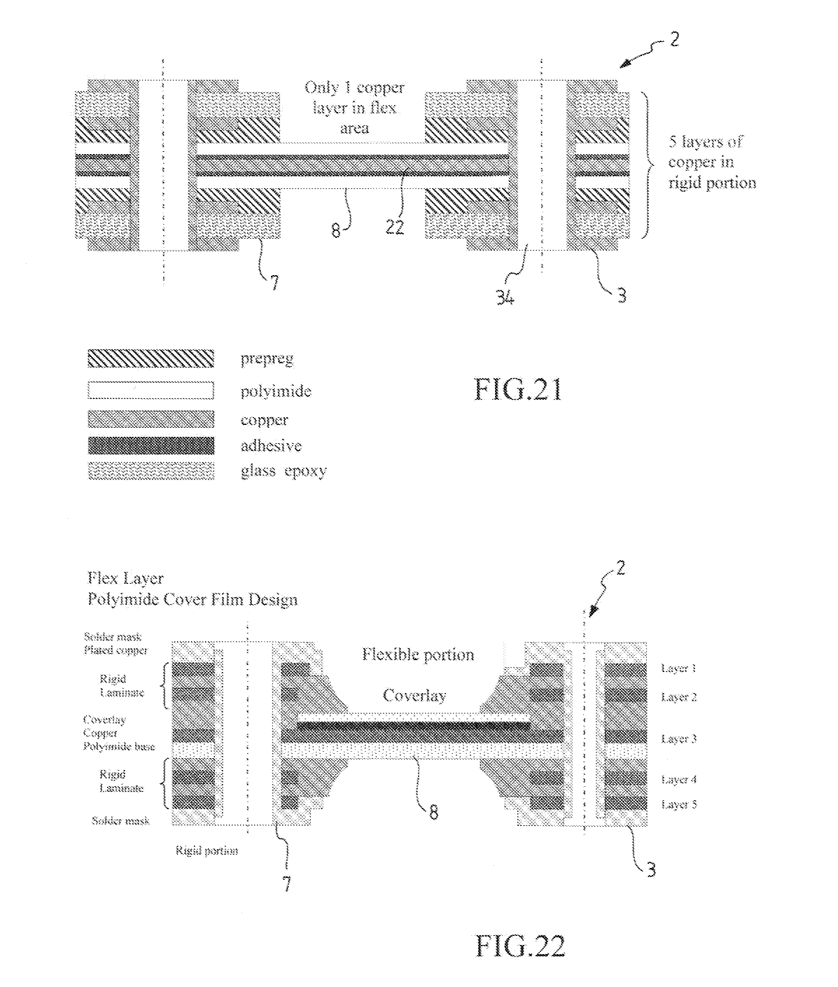

In the embodiment illustrated in FIG. 21, the base 2 comprises a further multi-layer substrate 7 connected to a multi-layer substrate 3, through a flexible intermediate wing 8.

The substrate 3 and the further substrate 7 comprise a stack of identical layers with the same central core of overlying layers that define the flexible wing 8. According to such an embodiment, the central core comprises a single inner layer of copper 22 to make electrical connection tracks between the flexible wing 8 and, respectively, the substrate 3 and the further substrate 7. The substrate 3 and the further substrate 7 may also have suitable metalized vias 34.

In the embodiment illustrated in FIG. 22, the base 2 has a configuration substantially corresponding to the one illustrated in FIG. 21, even if the layers have a different thickness and alternate differently to satisfy suitable design requirements, like the number of connections necessary per unit area and other design factors. According to the present embodiment, some layers that make the substrate 3 or the further substrate 7 and/or the intermediate wing 8, may have a curved fitting profile.

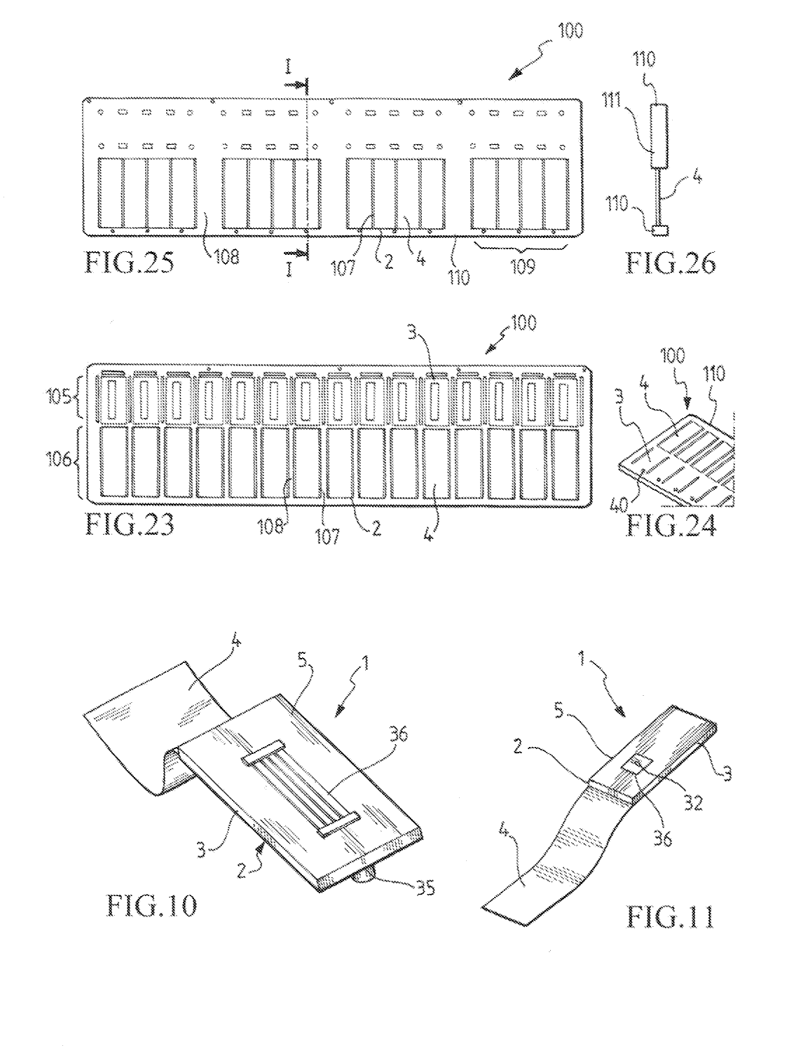

In a second embodiment, a package 1, illustrated in FIG. 10, comprises the multi-layer substrate 3 with a connection pin 35 projecting from the opposite side to the protective envelope 5, said pin being suitable for allowing rapid connection to a printed circuit board PCB.

In such an embodiment, the protective envelope 5 also has a window 36 of predetermined size at the surface opposite the substrate 3. Such a window 36 allows possible interactions between the MEMS components, housed on the substrate 3, and an external environment for sensing, printing ink, and fluids and gas handling.

The package/thus obtained has great freedom of connection, thanks to the flexible wing 4 projecting from the substrate 3, as well as the possibility of making the MEMS components interact with the outside.

In accordance with a third embodiment, illustrated in FIG. 11, a package/has, in particular, on the protective envelope 5, a window 36, of predetermined size at the opposite surface to the substrate 3. The window 36 makes it possible to identify a contact 32 or electrical connection pad between the MEMS component housed on the substrate 3 and an external connection, as shown in FIG. 11.

Such a variant embodiment of the package for MEMS according to an embodiment of the invention makes it possible, in particular, to associate versatility of connection, given by the flexible wing 4, with the possibility of electrically connecting the MEMS components contained in the protective envelope 5 directly with external connection tracks.

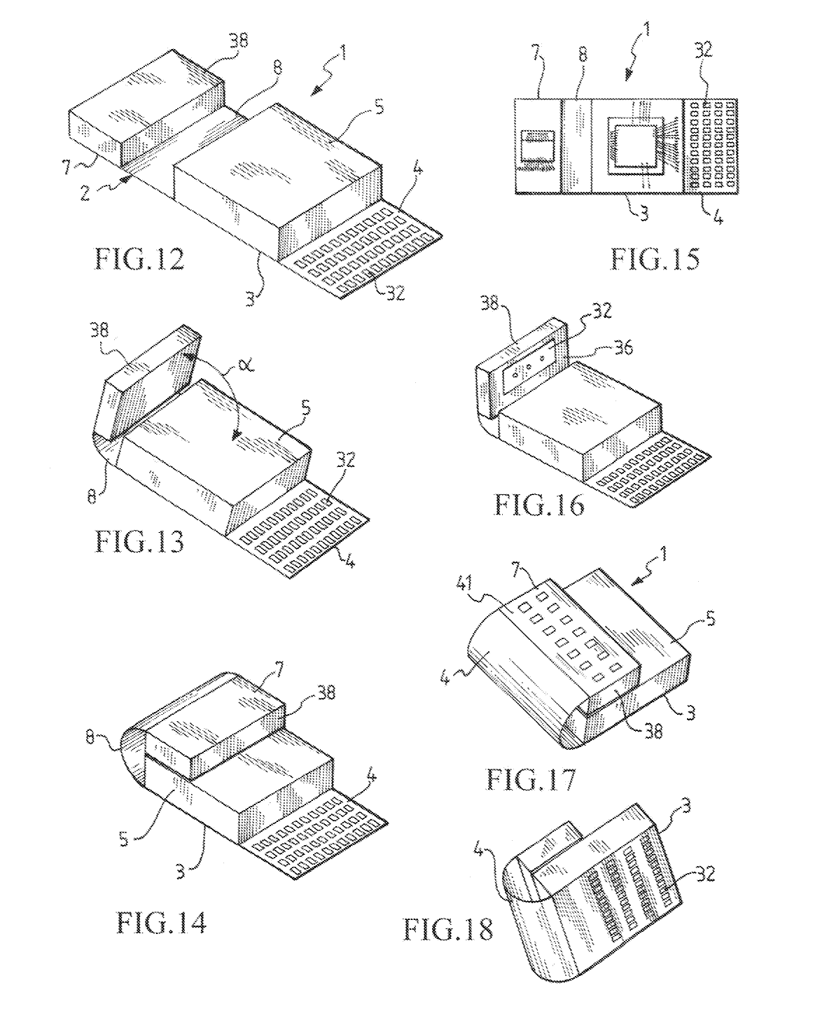

In accordance with a fourth embodiment, illustrated in FIGS. 12, 13 and 14, a package/comprises a base 2, illustrated in FIG. 15, which has a multi-layer substrate 3 and a flexible wing 4, projecting from said substrate 3. The base 2, of the present embodiment, has a further multi-layer substrate 7 connected to the substrate 3 by means of a flexible intermediate wing 8.

Such a further substrate 7 is made, in a substantially similar way to the substrate 3, as a multi-layer structure comprising at least one layer of composite material. In particular, the base 2 is a printed circuit board PCB.

Of course, the intermediate wing 8 could be made comprising an analogous or different number of layers with respect to the number of layers that make up the flexible wing 4, according to the design requirements. The base 2 is, a monolithic element suitable for being connected to external connection tracks, like for example printed circuit boards PCB or other.

On top of the substrate 3 MEMS components are associated and a protective envelope 5 is made and, similarly, on top of the further substrate 7 further MEMS components are associated and a further protective envelope 38 is made.

The package/thus obtained has further degrees of freedom in terms of its spatial arrangement. Indeed, the further protective envelope 38 and the protective envelope 5 may be arranged with an angle α between them that is variable from approximately 0°-90°-180° as illustrated in FIGS. 14, 13 and 12, respectively.

In particular, as illustrated in FIG. 14, the further substrate 7 may at least partially lay over the substrate 3.

In accordance with a variant embodiment of the further protective envelope 38, the surface opposite the further substrate 7 may be equipped with a window 36 variously shaped and used to expose a MEMS for connection with the external environment or on the further substrate 7 and possible external connection tracks, folded relatively to the MEMS as illustrated in FIG. 16.

Of course, the protective envelope 5 may also have a window for an electrical connection and/or for an interaction with the surrounding environment.

A fifth embodiment of the package is illustrated in FIGS. 17 and 18. The package/comprises, in a similar way to what has been illustrated earlier, a base 2 made in a single body and made up of a substrate 3 and a further substrate 7 connected together by the same flexible wing 4.

According to such an embodiment, the package/has suitable first and second electrical connection pads 32 made on the lower surface, respectively, of the further substrate 7 and of the substrate 3.

The package/thus made has great flexibility of arrangement allowing, in particular, the further protective envelope 38, made on top of the further substrate 7, to be laid on the envelope 5 made on top of the substrate 3 and to be respectively associated with external connection tracks, which may even be different from one another.

An embodiment of the present invention also refers to a process for manufacturing a package for micro-electro-mechanical systems of the MEMS type of the type described above for which details and cooperating parts with the same structure and function shall be indicated with the same reference numerals and reference marks.

As already seen, the package/is substantially box-shaped and comprises a base 2, for the assembly of MEMS components, and a protective envelope 5 for containing and protecting such MEMS components.

A process according to an embodiment of the present invention comprises the following steps of:

providing a base 2 comprising a multi-layer substrate 3 with at least one layer 25 of composite material and at least one flexible wing 4 projecting from the substrate 3, such a base 2 being made as a monolithic element;

associating the MEMS components with the base 2;

making the protective envelope 5 for the base 2;

connecting the base 2 to external connection tracks.

According to a process of an embodiment of the present invention, the base 2 is made as a printed circuit board PCB.

According to an embodiment of the present invention, the process foresees:

making a multi-layer strip 100 comprising a rigid edge 110 and a plurality of bases 2, suitably arranged side-by-side and removably associated with the rigid edge 110, as illustrated in FIG. 23.

Suitably, the strip 100 is obtained by using PCB technology to make printed circuit boards. The strip 100 has a plate-shaped configuration with a rigid edge 110 and this allows it to be particularly easy to handle and allows the use of suitable machinery for the positioning and gluing, or rather the assembly of the MEMS components, like for example those known by the name pick and place, to obtain the package.

The strip 100 is thus obtained as an overlapping of a plurality of layers piled with variable sequence and separately micro-processed with PCB (Printed Circuit Board) technology through precision mechanical micromachining, like for example numerical control milling, and suitable three-dimensional metallizations to obtain metalized through holes and/or buried channels and channels for fluidics routing through the substrate.

The layers that make up the strip 100 are connected together in a single final pressure assembly step.

The strip 100, according to a first embodiment illustrated in FIG. 23, is made with a first rigid portion 105 and a second flexible portion 106 obtained as a monolithic element with two thicknesses and suitable for defining for each base 2, respectively, the substrate 3 and the flexible wing 4 projecting from the substrate 3.

In particular, the first rigid portion 105 comprises an inner layer of composite material sandwich-incorporated between conductive layers and adhesive layers, with the interposition of at least one plastic layer, similarly to what has been described earlier for the package 1. The inner layer of composite material may be a layer alternatively of type-4 Flame Retardant (FR4), of Bismaleimide-Triazine (BT), liquid crystal polymer (LCP) or CEM-1 laminate, or else a layer of aluminium with a thickness of from 50-1000 μm. The inner layer is the heart of the substrate 3 and defines in particular its rigidity.

According to the embodiment illustrated in FIG. 8, the substrate 3, and therefore the first rigid portion 105, is formed from a stacked structure of piled up layers and comprises in sequence starting from the bottom, a lower coating layer 30, a pair of lower conductive layers 22A and 22B, generally made from copper or conductive material coated in copper, a layer of adhesive material 27 and a layer of plastic material 28, which has a further adhesive layer 24 and an inner layer 25 of composite material laying on it. On top of the inner layer 25 there is a pair of upper conductive layers 26A and 26B and finally an upper coating layer 29. As already indicated, the upper and lower coating layers 29, 30 are formed from an insulating paint known as “solder resist” or “solder mask” that allows some portions of strip 100 to also be protected from oxidation and from undesired electrical contacts.

The flexible wing 4, or rather the second flexible portion 106 of the strip 100, on the other hand, is made as superposition of a portion of the plastic layer 28a and of a portion 27a of the adhesive layer 27 obtained as extension of the same plastic and adhesive layers 28, 27, respectively, which make up the substrate 3. The second flexible portion 106 thus has a substantially lower thickness than the thickness of the first rigid portion 105 and in particular has specific characteristics of rigidity.

The strip 100 may be formed from further adhesive layers or may comprise one or more insulating layers of pre-preg, which is a fabric made of glass mixed with resin, arranged between the layers indicated above.

According to an embodiment illustrated in FIG. 23, the strip 100 may be designed and arranged to obtained the bases 2 aligned, equally spaced by means of rigid separator elements 108 which allow the strip 100 to be stiffened. Moreover, there are slits 107 at the rigid elements 108 to make it easier to detach each base 2 from the strip 100 at the end of the process.

Of course, the composition of the layers of the first rigid portion 105 and of the second flexible portion 106, which respectively define the substrate 3 as well as the flexible wing 4 of each base 2, is variable according to the layout requirements.

On the lower surface of the first rigid portion 105 pins 35 may be made for a rapid connection of each base 2 to a printed circuit board PCB or fixture. These pins may be accurately formed my moulding so that they may subsequently be used to accurately align the electrical connections and the MEMS structures to the PCB or functional fixture. An example of the alignment to a functional fixture would be the alignment of ink channels in the MEMS to channels that carry the ink in a plastic or metal support fixture.

Furthermore, on the first rigid portion 105 and on the second flexible portion 106 internal electrical connection tracks can be made that have a configuration according to the design layout.

On the strip 100 thus obtained the MEMS components are assembled through suitable machinery. Of course, the MEMS components may be housed at each substrate 3 or else at the second flexible portion 106, according to requirements.

Finally, through molding the protective envelope 5 is made on top of each substrate 3 of each base 2 to define a package of the full-molded type.

In accordance with a variant embodiment of the strip 100, as illustrated in FIGS. 25 and 26, groups 109 of bases 2 are side-by-side one another and separated by rigid elements 108.

According to such an embodiment, for each group 109 of bases 2, the substrates 3 form a single substrate body 111 from which a plurality of flexible wings 4 project.

Prearranged slits 107 divide the flexible wings 4 from the rigid elements 108 and from each other, to make the step of separating each group 109 from the rigid edge 110 easy.

The strip 100, illustrated in FIG. 25, allows packages to be made with further degrees of freedom of connection to external connection tracks.

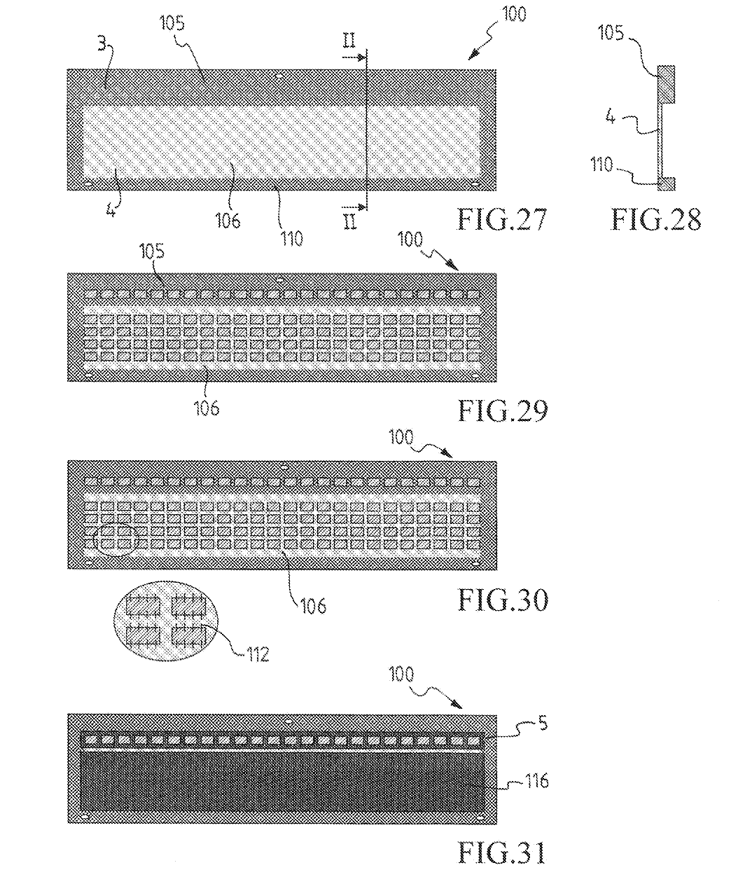

In accordance with a further variant of the strip 100, illustrated in FIGS. 27 and 28, the first rigid portion 105 is continuous and is associated with the rigid edge 110 forming a single substrate body, whereas the second flexible portion 106 projects from the first rigid portion 105 and from the rigid edge 110 forming a single flexible wing body.

Suitable holes are made at the rigid edge 110 to move and attach the strip during the assembly steps. By using such a configuration of strip 100, the process foresees the step of housing, both at the first rigid portion 105 and at the second flexible portion 106, a plurality of MEMS components connected with suitable internal connection tracks 112, as illustrated in FIGS. 29 and 30.

Finally, the process foresees the step of making a first protective envelope 5 to cover the entire first rigid portion 105 and a second protective envelope 116 to cover the second flexible portion 106, as illustrated in FIG. 31. A portion of the second flexible portion 106 with an edge in contact with the first rigid portion 105 may be envelopless and defines a flexible intermediate wing 8, which allows the packages illustrated in FIGS. 17 and 18 to be obtained.

Of course, according to a further variant that has not been illustrated in the figures, the strip can be made comprising an alternating sequence of first rigid portions and of second flexible portions, to make for each base 2 respective substrates 3 and further substrates 7 alternating with one another by suitable flexible intermediate wings 8. A package obtained with such a strip is illustrated in FIGS. 12 and 17.

Such packages may allow the protective envelopes made on top of respective substrates to be partially or totally laid on top of one another, with further freedoms of connection to external connection tracks.

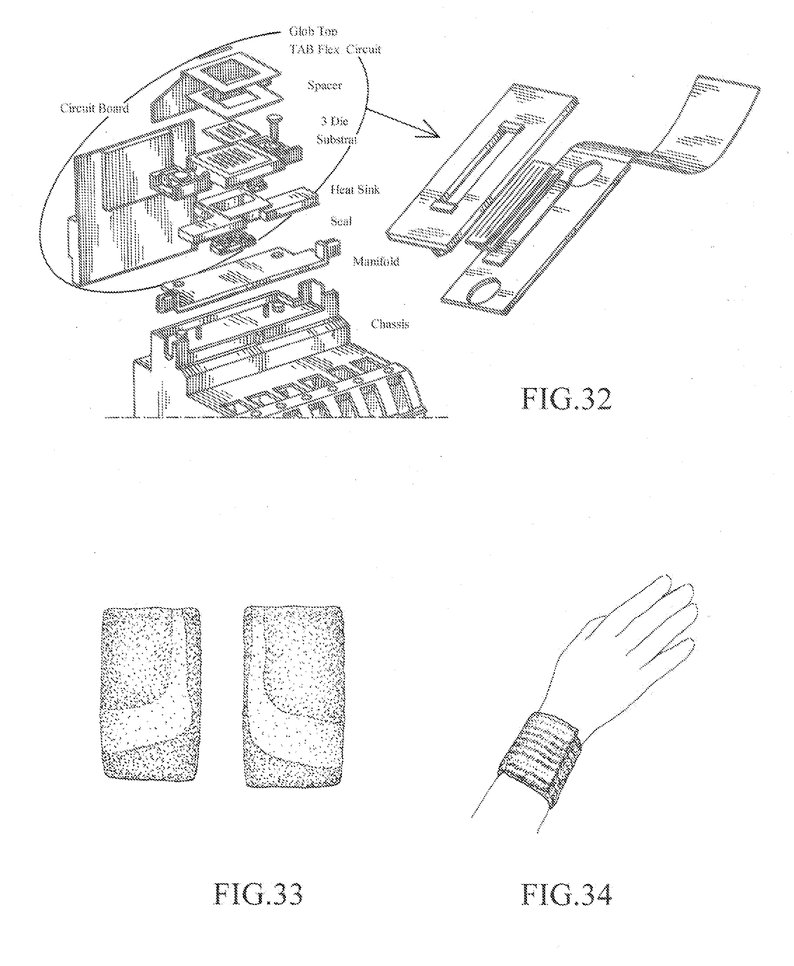

Some examples of devices that use packages according to an embodiment of the present invention are illustrated in FIGS. 32, 33 and 34.

In particular, FIG. 32 illustrates a package used as a component of a printer head, to obtain a reliable head with a smaller size.

FIGS. 33 and 34 show two medical applications; in this case the package is integrated in suitable wrist bands associated with prearranged electrical circuits and allows some functional characteristics of the person wearing the wrist band to be detected.

An advantage of a package according to an embodiment of the present invention is its unusual versatility as well as its freedom of connection with external connection tracks. The base, made with PCB technology and comprising the flexible wing formed in a single body with the substrate, allows the package to be connected with maximum freedom without being constrained to any arrangement and allows excellent protection of the MEMS components, through the protective envelope made on the base itself.

Another advantage of a package according to an embodiment of the present invention is given by its flexibility, the base indeed allowing substrates and flexible wings to be made in alternation according to the design requirements in relation to the MEMS components housed in the package.

Another advantage of a the package according to an embodiment of the present invention is given by the possibility of obtaining an extremely accurate base made through precision mechanical micromachining made on each layer that makes up the base, all technologies used to make printed circuit boards PCB, and create fluidics channels, holes in the rigid substrate to be connected with the silicon chip. Another advantage of a package made according to an embodiment of the present invention is given by the possibility of reducing the complexity of the printed circuit board with which it will be associated. Indeed, the base of the package may integrate in itself a portion of the connection tracks between the MEMS components housed in the substrate assembly allowing the external electrical connection tracks to be reduced.

An embodiment of the structure/may be part of a system such as a computer system.

Naturally, in order to satisfy local and specific requirements, a person skilled in the art may apply to the embodiments described above many modifications and alterations. Particularly, although one or more embodiments have been described with a certain degree of particularity, it should be understood that various omissions, substitutions, and changes in the form and details as well as other embodiments are possible. Moreover, it is expressly intended that specific elements and/or method steps described in connection with any disclosed embodiment may be incorporated in any other embodiment as a general matter of design choice.

What is claimed is:

1. Package for Micro-Electro-Mechanical Systems of the MEMS type comprising:
a base for the assembly of MEMS components;
a protective envelope for containing said MEMS components;
wherein said base is a multi-layer structure with at least one layer of composite material that makes a substrate and at least one flexible wing projecting from said substrate, said base being a monolithic element suitable for being connected to external connection tracks.

2. Package according to claim 1 wherein said at least one layer of composite material is selected from Flame Retardant 4 (FR4), Bismaleimide-Triazine resin (BT), liquid crystal polymer (LCP) or aluminium with a thickness of from 50 to 1000 μm.

3. Package according to claim 2 wherein said flexible wing comprises at least one portion of at least one layer of material included in said multi-layer structure forming said substrate.

4. Package according to claim 1 wherein said flexible wing comprises a layer of said at least one layer of composite material.

5. Package according to claim 3 wherein said protective envelope is made from plastic material and is associated with said base to incorporate MEMS components associated with said substrate and/or with said flexible wing to define said package of the full-molded type.

6. Package according to claim 5 wherein said base comprises a further multi-layer substrate comprising said at least one layer of composite material and connected to said substrate by means of a flexible intermediate wing projecting from said further substrate and from said substrate.

7. Package according to claim 6 wherein said substrate comprises at least one connection pin projecting from the opposite side to said protective envelope.

8. Package according to claim 7 wherein said protective envelope comprises at least one connection window at the surface opposite with respect to said substrate to allow an interaction between said MEMS components and said external connection tracks.

9. Process for manufacturing a package for micro-electro-mechanical systems of the MEMS type that comprises a base for the assembly of MEMS components and a protective envelope for containing said MEMS components, comprising the following steps of:
providing a multi-layer structure that defines a base comprising a substrate, with at least one layer of composite material, and at least one flexible wing projecting from said substrate, said base being a monolithic element;
associating said MEMS components with said base;
making said protective envelope for said base;
connecting said base to external connection tracks.

10. Process according to claim 9 wherein said layer of composite material alternately with a layer of Flame Retardant 4 (FR4) or of Bismaleimide-Triazine resin (BT) or of liquid crystal polymer (LCP) or of aluminium with a thickness of from 50 to 1000 μm.

11. Process according to claim 10 further comprising forming each base as an extension of at least one portion of a layer of material that makes up said multi-layer structure forming said substrate.

12. Process according to claim 9 further comprising forming said flexible wing comprising a layer of said at least one layer of composite material.

13. Process according to claim 11, further comprising making said protective envelope by molding of a plastic material to incorporate MEMS components associated with said substrate and/or with said flexible wing to define said package of the full-molded type.

14. Process according to claim 13, further comprising forming said base comprising a further multi-layer substrate with at least one layer of composite material and by making a flexible intermediate wing projecting from said further substrate and from said substrate.

15. Process according to claim 14, further comprising:
making said protective envelope on top of said substrate and making a further protective envelope on top of said further substrate
at least partially laying said further protective envelope on said protective envelope.

16. Process according to claim 15, further comprising forming at least one pin in said substrate on the opposite surface to said protective envelope.

17. Process according to claim 9 further comprising forming a strip having a rigid edge associated with a first rigid portion and a second flexible portion projecting from said first rigid portion, said first rigid portion and said second flexible portion defining at least one of said base.

18. Process according to claim 17, further comprising forming on said strip a plurality of said bases, said bases being side-by-side one another and separated by means of a plurality of rigid elements.

19. Process according to claim 18, further comprising forming at least one group of bases having a single die body and a plurality of flexible wings projecting from said single die body.

20. Printer head comprising at least one MEMS system with a package made according to claim 1.

21. Medical device having a flexible band comprising at least one MEMS system with a package made according to claim 1.

22. Use of a package according to claim 1 to make a device comprising at least one MEMS system.

23. An apparatus, comprising:
a first housing; and
a first substrate disposed in the first housing and including a first layer having a first portion that extends out from the housing.

24. The apparatus of claim 23 wherein the housing comprises a resin.

25. The apparatus of claim 23 wherein the housing is rigid.

26. The apparatus of claim 23 wherein the substrate comprises a printed-circuit-board substrate.

27. The apparatus of claim 23 wherein the substrate comprises a second layer that is disposed entirely within the housing.

28. The apparatus of claim 23 wherein the substrate comprises a second layer having a portion that extends out from the housing and that is disposed over the portion of first layer.

29. The apparatus of claim 23 wherein the portion of the first layer that extends from the housing is flexible.

30. The apparatus of claim 23 wherein the first layer comprises a conductive material.

31. The apparatus of claim 23 wherein the first layer comprises an electrically insulating material.

32. The apparatus of claim 23, further comprising a circuit disposed on the substrate.

33. The apparatus of claim 23, further comprising:
a circuit disposed on the substrate; and
a conductive terminal that is coupled to the circuit and that is exposed through the housing.

34. The apparatus of claim 23, further comprising:
a circuit disposed on the substrate; and
a conductive terminal that is coupled to the circuit and that is disposed on the portion of the first layer that extends out from the housing.

35. The apparatus of claim 23, further comprising:
a micro-electromechanical device disposed on the substrate; and
a conductive terminal that is coupled to the device and that is exposed through the housing.

36. The apparatus of claim 23, further comprising:
a micro-electromechanical device disposed on the substrate; and
a conductive terminal that is coupled to the device and that is disposed on the portion of the first layer that extends out from the housing.

37. The apparatus of claim 23, further comprising:
a second housing that is separate from the first housing; and
a second substrate disposed in the second housing and including a second portion of the first layer such that the first portion of the first layer extends out from the second housing.

38. The apparatus of claim 37, further comprising:
a first circuit disposed on the first substrate;
a second circuit disposed on the second substrate; and
wherein the first layer includes a conductive portion that couples together the first and second circuits.

39. The apparatus of claim 37, further comprising:
a first microelectromechanical device disposed on the first substrate;
a second microelectromechanical device disposed on the second substrate; and
wherein the first layer includes a conductive portion that couples together the first and second devices.

40. The apparatus of claim 37, further comprising:
a microelectromechanical device disposed on one of the first and second substrates;
a circuit disposed on the other of the first and second substrates; and
wherein the first layer includes a conductive portion that couples together the device and the circuit.

41. The apparatus of claim 23, further comprising:
wherein the first substrate includes a rigid portion and a flexible portion; and
at least one fluid path disposed in the rigid portion of the substrate.

42. The apparatus of claim 23, further comprising:
wherein the first substrate includes a rigid portion and a flexible portion;
at least one fluid path disposed in the rigid portion of the substrate; and
at least one through hole extending through the first substrate and into the at least one fluid path.

43. The apparatus of claim 23, further comprising:
wherein the first substrate includes a rigid portion and a flexible portion; and
at least one buried fluid path disposed in the rigid portion of the substrate.

44. The apparatus of claim 23, further comprising:
wherein the first substrate includes a rigid portion disposed outside of the housing and a flexible portion; and
at least one fluid path disposed in the rigid portion of the substrate.

45. The apparatus of claim 23, further comprising:
wherein the first substrate includes a rigid portion disposed outside of the housing and a flexible portion that includes a least a part of the first portion of the first layer; and
at least one fluid path disposed in the rigid portion of the substrate.

46. The apparatus of claim 23, further comprising:
wherein the first substrate includes a rigid portion that includes at least part of the first portion of the first layer and includes a flexible portion; and
at least one fluid path disposed in the rigid portion of the substrate.

47. A system, comprising:
an apparatus, comprising
a housing, and
a first substrate disposed in the housing and including a layer having a portion that extends out from the housing; and
an integrated circuit coupled to the apparatus.

48. The system of claim 41 wherein the integrated circuit comprises a second substrate.

49. The system of claim 41 wherein the integrated circuit is electrically coupled to the first substrate through an opening in the housing.

50. The system of claim 41 wherein:
the layer includes a conductor; and
the integrated circuit is electrically coupled to the first substrate via the layer.

51. The system of claim 41, further comprising:
a printed circuit board; and
wherein the portion of the layer is attached to the printed circuit board.

52. The system of claim 41, further comprising:
a printed circuit board; and
wherein the housing is attached to the printed circuit board.

53. A method, comprising:
forming a first structure including a first layer having a first size in a first dimension and a second layer having a second size in the first dimension, the second size greater than the first size; and
encapsulating the first layer and a first portion of the second layer such that a second portion of the second layer remains unencapsulated.

54. The method of claim 47, further comprising:
wherein forming the structure comprises forming the structure including a third layer having substantially the first size in the first dimension; and
encapsulating the third layer.

55. The method of claim 47, further comprising:
wherein forming the structure comprises forming the structure including a third layer having substantially the second size in the first dimension; and
encapsulating a first portion of the third layer such that a second portion of the third layer remains unencapsulated.

56. The method of claim 47 wherein forming the second layer comprises forming the second portion of the second layer from a conductive material.

57. The method of claim 47 wherein forming the second layer comprises forming the second portion of the second layer from a flexible material.

58. The method of claim 47, further comprising forming a microelectromechanical device in one of the layers.

59. The method of claim 47, further comprising forming an electronic component in one of the layers.

60. The method of claim 47 wherein forming the structure comprises forming the second layer such that an edge of the second layer that is transverse to the first dimension is substantially aligned with an edge of the first layer that is transverse to the first dimension.

61. The method of claim 47 wherein forming the structure comprises forming the second layer such that edges of the second layer that are substantially parallel to the first dimension are substantially aligned with edges of the first layer that are substantially parallel to the first dimension.

62. The method of claim 47 wherein forming the structure comprises forming the second layer such that an edge of the second layer that is substantially perpendicular to the first dimension is substantially aligned with an edge of the first layer that is substantially perpendicular to the first dimension.

63. The method of claim 47, further comprising:
forming a second structure including a third layer having a third size in the first dimension and the second layer, the third size smaller than the second size; and
encapsulating the third layer and a third portion of the second layer such that the second portion of the second layer remains unencapsulated.

64. The method of claim 47, further comprising forming at least a portion of a fluid channel in the second portion of the second layer.

65. The method of claim 47, further comprising forming at least a portion of a fluid channel in a rigid region of the second portion of the second layer.

66. The method of claim 47, further comprising forming at least a portion of a fluid channel in a rigid region of the second portion of the second layer, the second portion of the second layer also having a flexible portion.
